(19) United States
(12) Patent Application Publication
(10) Pub. No.: US 2025/0201683 A1
(43) Pub. Date: Jun. 19, 2025

(54) MOLDED VERTICAL INTERCONNECT ARRAY

(71) Applicant: ANALOG DEVICES, INC., Wilmington, MA (US)

(72) Inventors: Michael John Anderson, Campbell, CA (US); John David Brazzle, Tracy, CA (US); Chaitrali Joshi, San Jose, CA (US)

(21) Appl. No.: 18/545,526

(22) Filed: Dec. 19, 2023

(51) Int. Cl. H01L 23/498; H01L 21/48; H01R 12/52; H05K 1/11; H05K 3/40

(52) U.S. Cl. CPC H01L 23/49811; H01L 21/4853; H01R 12/52; H05K 1/11; H05K 3/4015

(57) ABSTRACT

An integrated device package is disclosed. The integrated device package can include a substrate and one or more vertical interconnect arrays comprising a plurality of vertical interconnects in an array and a molding compound encapsulating the plurality of vertical interconnects. The molding compound can include a planar surface at a first end and a second end of the one or more vertical interconnect arrays. A first end and a second end of the plurality of vertical interconnects can be substantially co-planar with the molding compound at the first end and the second end of the one or more vertical interconnect arrays. The first end of the one or more vertical interconnect arrays can physically and electrically connected to a first side of the substrate and extend outwardly from the substrate.

### BACKGROUND

### Field

The field relates to electronic modules for high power applications.

### Description of the Related Art

Advancements have been made to improve the integration and performance of microelectronic devices. As microelectronic devices become more complex, the importance of packaging solutions have been developed to address the challenges posed by high power requirements and demands for compact and efficient designs.

### SUMMARY

For purposes of summarizing the disclosure and the advantages achieved over the prior art, certain objects and advantages of the disclosure are described herein. Not all such objects or advantages may be achieved in any particular embodiment. Thus, for example, those skilled in the art will recognize that the invention may be embodied or carried out in a manner that achieves or optimizes one advantage or group of advantages as taught herein without necessarily achieving other objects or advantages as may be taught or suggested herein.

All of these implementations are intended to be within the scope of the invention herein disclosed. These and other implementations will become readily apparent to those skilled in the art from the following detailed description of the preferred implementations having reference to the attached figures, the invention not being limited to any particular preferred implementations disclosed.

In one implementation an integrated device package can include: a substrate; and one or more vertical interconnect arrays including a plurality of vertical interconnects in an array and a molding compound encapsulating the plurality of vertical interconnects, wherein the molding compound at a first end and a second end of the one or more vertical interconnect arrays include a planar surface, and wherein a first end of the plurality of vertical interconnects is substantially co-planar with the molding compound at the first end of the plurality of vertical interconnects and a second end of the plurality of vertical interconnects is substantially co-planar with the molding compound at the second end of the plurality of vertical interconnects; wherein the first end of the one or more vertical interconnect arrays is physically and electrically connected to a first side of the substrate, the one or more vertical interconnect arrays extending outwardly from the substrate.

In some implementations, the plurality of vertical interconnects are arranged in a horizontal orientation such that a length of the plurality of vertical interconnects is greater than a height. In some implementations, the plurality of vertical interconnects are arranged in a vertical orientation such that a height of the plurality of vertical interconnects is greater than a length. In some implementations, the one or more one or more vertical interconnect arrays includes a singulated vertical interconnect array. In some implementations, lateral sides of the plurality of vertical interconnects are over molded. In some implementations, one or more lateral sides of the one or more vertical interconnect arrays protrude through the molding compound. In some implementations, the plurality of vertical interconnects are partially molded such that a at least a portion of a height and one or more sides of the plurality of vertical interconnects protrude through the molding compound.

In some implementations, the integrated device package includes a second substrate, wherein the second side of the one or more vertical interconnect arrays is physically and electrically connected to a first side of the second substrate by a conductive adhesive. In some implementations, the one or more vertical interconnect arrays are surface mounted to the substrate. In some implementations, the one or more vertical interconnect arrays are connected to the substrate with a conductive adhesive. In some implementations, the conductive adhesive includes solder. In some implementations, the conductive adhesive includes conductive epoxy. In some implementations, the one or more vertical interconnect arrays are mounted to the second substrate with a conductive adhesive. In some implementations, the conductive adhesive includes solder. In some implementations, the conductive adhesive includes conductive epoxy.

In some implementations, an aspect ratio of the plurality of vertical interconnects is at least 1:5. In some implementations, the molding compound includes thermoset resin. In some implementations, the integrated device package includes a scam between each of the one or more vertical interconnect arrays connected to the first substrate. In some implementations, a plurality of electrical components are mounted to the substrate. In some implementations, a width of the plurality of vertical interconnects varies and a length is constant. In some implementations, a width and a length of the plurality of vertical interconnects varies and a height is constant. In some implementations, the one or more vertical interconnect arrays include a one-dimensional array. In some implementations, the one or more vertical interconnect arrays include a two-dimensional array.

In another implementation, an integrated device package can include: one or more vertical interconnect arrays including a plurality of vertical interconnects in an array and a molding compound encapsulating the plurality of vertical interconnects, wherein the molding compound at a first end and a second end of the one or more vertical interconnect arrays include a planar surface, and wherein a first end of the plurality of vertical interconnects is substantially co-planar with the molding compound at the first end of the plurality of vertical interconnects and a second end of the plurality of vertical interconnects is substantially co-planar with the molding compound at the second end of the plurality of vertical interconnects arrays; a first substrate, wherein the first end of the one or more vertical interconnect arrays is physically and electrically connected to a first side of the substrate; a second substrate, wherein the second end of the one or more vertical interconnect arrays is physically and electrically connected to a first side of the second substrate; and a seam between each of the one or more vertical interconnect arrays connected to the first and second substrate; wherein the one or more vertical interconnect arrays are disposed between the first and second substrates.

In some implementations, the plurality of vertical interconnects are arranged in a horizontal orientation such that a length of the plurality of vertical interconnects is greater than a height. In some implementations, the plurality of vertical interconnects are arranged in a vertical orientation prior to encapsulating such that a height of the plurality of vertical interconnects is greater than a length. In some implementations, a width of the plurality of vertical interconnects varies and the length is constant. In some implementations, a width and length of the plurality of vertical interconnects varies and the height is constant. In some implementations, the molding compound encapsulating the plurality of vertical interconnects is singulated prior to mounting the one or more vertical interconnect arrays. In some implementations, lateral sides of the plurality of vertical interconnects are over molded. In some implementations, one or more lateral sides of the plurality of vertical interconnects protrude through the molding compound. In some implementations, the plurality of vertical interconnects are partially molded such that a section of a height and one or more sides of the plurality of vertical interconnects protrude through the molding compound.

In some implementations, the one or more vertical interconnect arrays are surface mounted to the first substrate and the second substrate. In some implementations, pre-molded vertical interconnect array is mounted to the first substrate and second substrate with a conductive adhesive. In some implementations, the conductive adhesive includes solder. In some implementations, the conductive adhesive includes conductive epoxy.

In some implementations, an aspect ratio of the plurality of vertical interconnects is at least 1:5. In some implementations, the molding compound includes thermoset resin. In some implementations, the molding compound is flush with the first end and the second end of the plurality of vertical interconnects. In some implementations, the one or more vertical interconnect arrays include planarized surfaces.

In some implementations, electrical components are mounted to the first substrate and second substrate. In some implementations, the one or more vertical interconnect arrays include a one-dimensional array. In some implementations, the one or more vertical interconnect arrays include a two-dimensional array.

In another implementation, a method of forming an electronic module can include: arranging a plurality of vertical interconnects in an array; encapsulating the plurality of vertical interconnects in a molding compound, wherein a first end and a second end of the plurality of vertical interconnects protrude through the molding compound; and after the encapsulating, singulating the encapsulated plurality of vertical interconnects in an array into a plurality of vertical interconnect arrays.

In some implementations, the method includes planarizing a first surface of the one or more vertical interconnect arrays and a second surface opposite the first surface. In some implementations, the method includes mounting a first end of at least one of the plurality of molded vertical interconnects to a substrate. In some implementations, the method includes mounting a second end of the at least one of the plurality of molded vertical interconnects to a second substrate. In some implementations, the method includes disposing the plurality vertical interconnect arrays onto a tape and reel for mounting. In some implementations, encapsulating the plurality of vertical interconnects in a molding compound includes transfer molding or compression molding.

### BRIEF DESCRIPTION OF THE DRAWINGS

Various implementations will be described hereinafter with reference to the accompanying drawings. These implementations are illustrated and described by example only and are not intended to limit the scope of the disclosure. In the drawings, similar elements have similar reference numerals.

FIG. 1 is a top schematic perspective view of an electronic assembly according to various implementations.

FIG. 2 is a schematic perspective view of a molding compound flowing between a substrate and a plurality of vertical interconnects.

FIG. 3 illustrates a perspective view of a vertical interconnect array having a molding compound encapsulating lateral sides of the vertical interconnect array.

FIG. 4 is a schematic perspective view of a vertical interconnect connected to a substrate in which an end of the vertical interconnect is substantially co-planar with the molding compound.

FIG. 5 illustrates a perspective view of another implementation of a vertical interconnect array in which one or more lateral sides of vertical interconnects protrude through a molding compound.

FIG. 6 is a perspective view of another implementation of a vertical interconnect array in which one or more lateral sides and at least a portion of a height of the vertical interconnects protrude through a molding compound.

FIG. 7-12 illustrate various perspective views of example vertical interconnect arrays with multiple vertical interconnects.

FIG. 13 illustrates an example process of processing vertical interconnect arrays having a horizontal orientation such that a length of the vertical interconnects is greater than a height, according to an implementation.

FIG. 14 illustrates another example process of processing vertical interconnect arrays having a horizontal orientation such that a length of the vertical interconnects is greater than a height in which a width of the vertical interconnects varies, according to an implementation.

FIG. 15 illustrates an example process of processing vertical interconnect arrays having a vertical orientation such that a height of vertical interconnects is greater than a length, according to an implementation.

FIG. 16 illustrates an example process of processing vertical interconnect arrays having a horizontal orientation such that a length of the vertical interconnects is greater than a height in which a width of the vertical interconnects varies, according to an implementation.

### DETAILED DESCRIPTION

The present disclosure may be understood by reference to the following detailed description. It is noted that, for purposes of illustrative clarity, certain elements in various drawings may not be drawn to scale, may be represented schematically or conceptually, or otherwise may not correspond exactly to certain physical configurations of embodiments.

As electronic assemblies increasingly utilize three-dimensional structures, the ability to route multiple high current electrical signals vertically between structures becomes increasingly important. Prior attempts to address the issue use a printed circuit board (PCB) in which traces on the PCB are routed between two planes. At a termination of the traces, plated castellations can be used to connect to solder balls to form solder fillets. This structure can then be mounted vertically to provide interconnections between two stacked devices, and solder is used to connect the castellation to the upper and lower stacked devices. While there can be multiple connections between the two assemblies, due to limitations of PCB manufacturing, and in particular the copper trace thickness, the current density capabilities of the interconnects is limited.

Thus, to facilitate such connections, packages and assemblies can utilize a molded vertical interconnect array for interconnection. A vertical interconnect can be an unplated (e.g., bare copper (Cu)) or plated (e.g., tin (Sn) plated) piece of copper that can be assembled using standard assembly equipment and techniques (chip shooters) but are limited in application. For example, a high aspect ratio vertical interconnect (e.g., relatively tall, but narrow) can be sensitive to tilt and rotation due to varying solder surface tensions during solder reflow. As the aspect ratio increases, the pitch between the vertical interconnects also increases due to the increase in the tendency of the vertical interconnects to tilt and/or rotate. Vertical interconnects are spaced farther apart to avoid causing a short at a connection pad during solder reflow. Therefore, as the aspect ratio of the vertical interconnects increase the minimum spacing and/or pitch of a set of vertical interconnects can also increase. This can result in suboptimal use of valuable space within an assembly that could otherwise be used to increase packing density and improve either product size or capabilities.

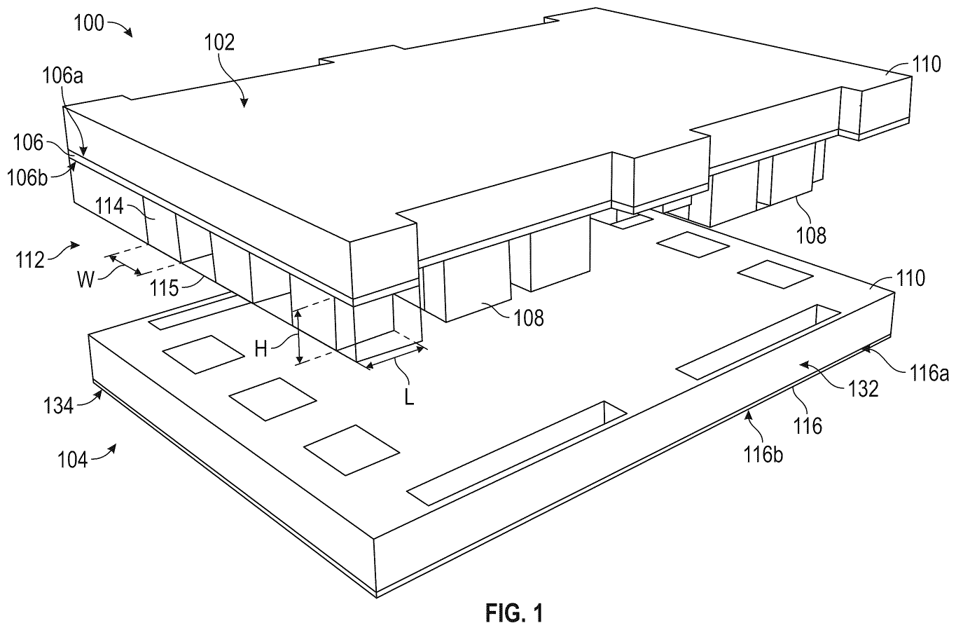

FIG. 1 illustrates an example electronic assembly 100 comprising a first integrated device package 102 and a second integrated device package 104. The first integrated device package 102 can include a substrate 106 (such as a package substrate, e.g., a printed circuit board, or PCB substrate) with surface mount technology (SMT) attached electronic components 108 mounted to a first surface 106a and/or second surface 106b of the substrate 106. Although a PCB substrate can be used for the substrate 106 in the example of FIG. 1, in other implementations, different types of substrates (such as lead frame substrates, ceramic substrates, etc.) may be used. For example, the electronic components 108 can be attached to pads or leads of the substrate 106 using a conductive adhesive, such as solder, a conductive epoxy, etc. In various implementations, the electronic components 108 can be pick-and-placed onto the substrate 106. The electronic components 108 can comprise any suitable type of electronic component, such as integrated device die(s), other types of active components, passive components (e.g., resistors, capacitors, inductors, field effect transistors (FETs), etc.), sensors, microelectromechanical systems (MEMs) components, or any other suitable type of component. For example, the electronic components 108 can include a combination of FETs and capacitors.

In some implementations, a molding and/or encapsulant compound 110 can be molded over at least portions of the electronic components 108 (e.g., molded over the first surface 106a and/or second surface 106b of substrate 106 to protect the electronic components 108 mounted thereto). In some implementations, the electronic components 108 can be completely embedded within the molding compounds 110. In other implementations, the molding compound 110 can be provided on both the top side 106a and a second surface 106b of the substrate 106 (e.g., molded over the first surface 106a and second surface 106b of the first integrated device package 102 to protect the electronic components 108 mounted thereto).

In some implementations, the first integrated device package 102 can further include one or more vertical interconnect arrays 112 comprising vertical interconnects 114 and a molding compound 115 encapsulating the vertical interconnects 114. The molding compound 115 can be similar and/or identical to encapsulant compound 110. For instance, one or more molding compounds 115 can be disposed together. The molding compound 115 can comprise a thermoset resin. Encapsulating the vertical interconnects 114 in the molding compound 115 can include includes transfer molding or compression molding. As mentioned above, high aspect ratio vertical interconnects (e.g., relatively tall, but narrow) can be sensitive to tilt and/or rotation due to varying solder surface tensions during reflow. The reflow process can involve the controlled application of heat to a conductive adhesive between electronic components (electronic components 108, vertical interconnect arrays 112, vertical interconnects 114, etc.) and a substrate (e.g., substrate 106 and/or substrate 116). Reflow can create a reliable and strong connection between the components and the substrate, enabling electrical and mechanical connections. It is during reflow that vertical connects having a high aspect ratio are susceptible to tilt and/or rotate. Such limitations can lead to minimum spacing and/or pitch of a set of vertical interconnects which need to be increased as the aspect ratio of the vertical interconnects being used is increased. This can result in suboptimal use of valuable space within the electronic assemblies that could otherwise be used to increase packing density and improve either product size and/or capabilities. Thus, by encapsulating the vertical interconnects 114 with the molding compound 115 before mounting to the substrate 106, the tendency of the vertical interconnects to tilt and/or rotate is reduced or eliminated allowing for the pitch between the vertical interconnects 114 to be decreased. The vertical interconnect arrays 112 can be formed in standardized sizes for case in customization for various applications.

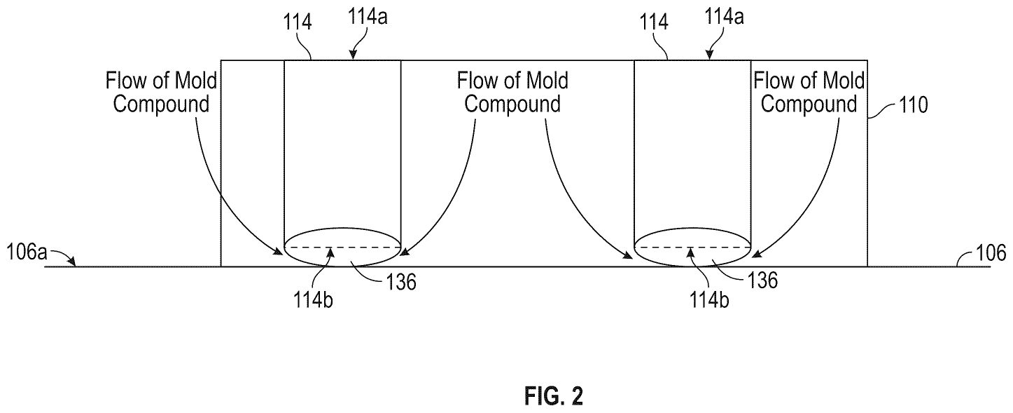

The vertical interconnect arrays 112 can be physically and/or electrically connected with a conductive adhesive (e.g., solder, a conductive epoxy, etc.) to the second surface 106b. The one or more vertical interconnect arrays 112 can be arranged along the second surface 106b in one or more directions. In some implementations, a seam can be formed between the molding compound 115 of the one or more vertical interconnect arrays 112. For example, the one or more vertical interconnect arrays 112 can abut one another and/or be disposed adjacent one another. The vertical interconnect arrays 112 can extend outwardly from the second surface 106b. In some implementations, the vertical interconnect arrays 112 can be taller than the electronic components 108 mounted on the second surface 106b. For example, the vertical interconnects 114 of the vertical interconnect arrays 112 can extend from substrate 106 and can extend beyond the electronic components 108. The vertical interconnect arrays 112 can be attached to the substrate 106 using SMT techniques. For example, in various implementations, the vertical interconnects 114 of the vertical interconnect arrays 112 can be picked and placed on the substrate 106 and attached to the substrate 106 using a conductive adhesive (e.g., solder, a conductive epoxy, etc.). In various implementations, the substrate 106 can include embedded conductors to electrically connect the vertical interconnect arrays 112 with the electronic components 108 on the first surface 106a, the electronic components 108 on the second surface 106b, and/or the electronic components 108 to one another. The vertical interconnect arrays 112 can provide a conductive path and connection (e.g., a solder or other suitable connection) to the second integrated device package 104. In some implementations, a first end 114a and/or second end 114b of the vertical interconnects 114 of FIG. 1 can be attached by a conductive adhesive 136 (e.g. soldered) to the substrate 106, which creates a spacing between the vertical interconnects 114 and the substrate 106 filled by the conductive adhesive 136. The vertical interconnects 114 can subsequently be overmolded, and the mold compound 110 can flow adjacent to and below the second end 114b of the vertical interconnects 114 around the conductive adhesive 136. As demonstrated in FIG. 2, the mold compound 110 thus is not co-planar with the second end 114b of the vertical interconnect 114 but rather fills the spacing around the conductive adhesive 136 and the vertical interconnects 114.

The second integrated device package 104 can include a substrate 116 (such as a package substrate, e.g., a printed circuit board, or PCB substrate) with surface mount technology (SMT) attached electronic components 108 mounted to a first surface 116a and/or second surface 116b of the substrate 116. In some implementations, the molding and/or encapsulant compound 110 can be molded over at least portions of the electronic components 108 (e.g., molded over the first surface 116a and/or second surface 116b of substrate 116 to protect the electronic components 108 mounted thereto). The substrate 116 can be physically and electrically connected to the vertical interconnect arrays 112 (e.g., with a conductive adhesive such as solder, conductive epoxy, etc.) of the first integrated device package 102 in any suitable manner. The vertical interconnect arrays 112 can be disposed between substrate 106 of the first integrated device package 102 and the substrate 116 of the second integrated device package 104. The substrate 116 can also include an electrical terminal(s) 134 formed on a second surface 116b of the substrate 116. In some implementations, the electrical terminals can be a molded ball grid array (BGA) package, a land grid array, and/or a vertical interconnect PCB connections.

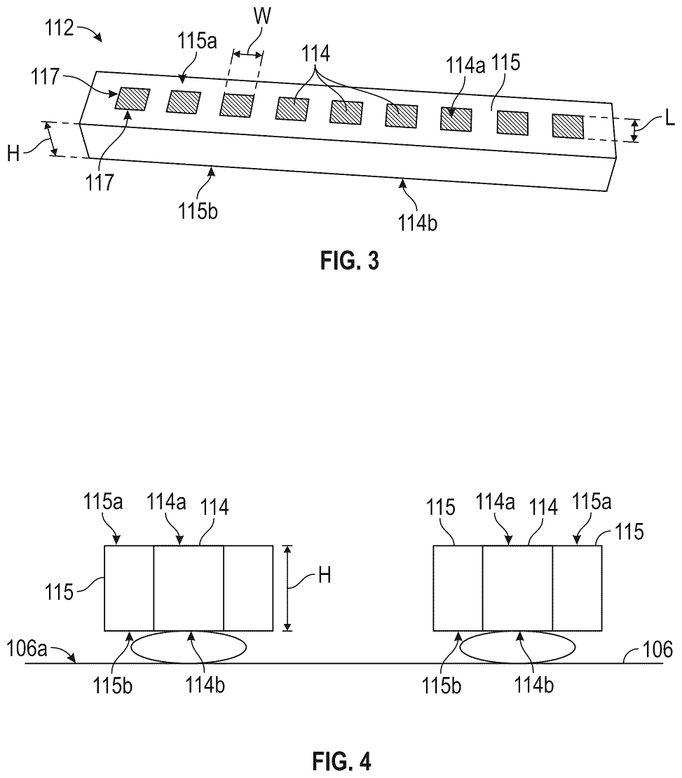

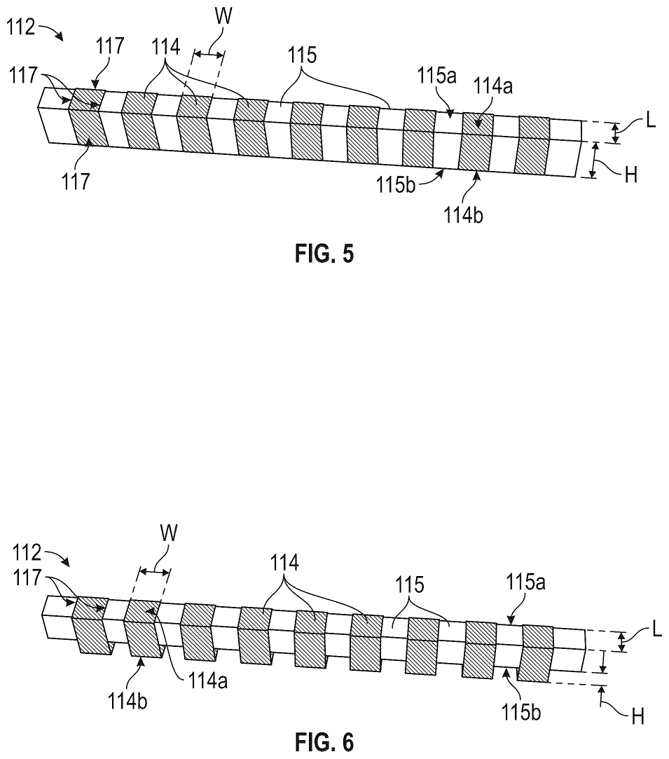

FIGS. 3-6 illustrate various implementations of the vertical interconnect array 112. FIG. 3 illustrates a perspective view of a vertical interconnect array 112 having a molding compound encapsulating lateral sides (e.g., all lateral sides 117). FIG. 4 illustrates a perspective view of a vertical interconnect 114 connected to the substrate 106 in which an end of the vertical interconnect 114a, 114b can be substantially co-planar with the molding compound 115 which contrasts the encapsulant compound 110 shown in FIG. 2 thus is not co-planar with an end of the vertical interconnect 114a, 114b. FIG. 5 illustrates a perspective view of another implementation of a vertical interconnect array 112 in which one or more lateral sides 117 of the vertical interconnects 114 are exposed through the molding compound 115. FIG. 6 is a perspective view of another implementation of the vertical interconnect array 112 in which one or more lateral sides 117 and at least a portion of a height H of the vertical interconnects 114 protrude through the molding compound 115. As shown in FIGS. 3 and 4, the molding compound 115 can have a planar surface at a first end 115a and/or a second end 115b of the vertical interconnect arrays 112. A first end 114a and a second end 114b of the plurality of vertical interconnects 114 can be substantially co-planar with the molding compound 115 at the first end 115a and the second end 115b of the vertical interconnect arrays 112. This is in contrast to the mold compound surrounding the conductive adhesive connecting the vertical interconnects 114 and substrate 106 of FIGS. 1 and 2 in which the mold compound is not co-planar with an end of the vertical interconnects 114. As shown in FIGS. 1 and 4, a Height H dimension of the vertical interconnects 114 can be transverse to the first surface 106a of the first substrate 106 when the vertical interconnect array 112 is attached to the substrate 106. As illustrated in FIG. 1, a length L dimension of the vertical interconnects 114 can be parallel to the largest length of the first substrate 106 when the vertical interconnect array 112 is attached to the substrate 106. Furthermore, a Width W dimension of the vertical interconnects 114 can be perpendicular to the largest length of the first substrate 106 when the vertical interconnect array 112 is attached to the substrate 106.

In some implementations, the vertical interconnect arrays 112 can comprise a singulated vertical interconnect array separated from a solid array of high density connections. The solid array can be singulated into various configurations based at least on the application of the singulated array. Additionally, the singulated vertical interconnect array can contain artifacts indicative of a singulation process such as saw markings, scratches, etc. In some implementations, as shown in FIGS. 5 and 6, one or more lateral sides 117 of the one or more vertical interconnect arrays 112 can protrude through the molding compound 115 while other lateral sides 117 can be remain encapsulated by the molding compound 115. In some implementations, as shown in FIG. 6, the plurality of vertical interconnects 114 can be at least partially encapsulated by the molding compound 115 such that a at least a portion of a Height H and one or more lateral sides 117 of the plurality of vertical interconnects 114 protrude through the molding compound 115. The Height H of the vertical interconnects 114 can be transverse to first surface 106a of the substrate 106. The vertical interconnect arrays 112 can comprise a one-dimensional array or a two-dimensional array.

Beneficially, the vertical interconnects 114 of the vertical interconnect arrays 112 can provide a suitable conductive interface for high currents (e.g., greater than or equal to 5 A, greater than 20 A per connection, greater than 50 A per connection, for example 120 A). For example, in some implementations, each vertical interconnect 114 can be shaped and selected to enable a current passing therethrough in a range of 1 A to 120 A, in a range of 5 A to 120 A, in a range of 5 A to 100 A, or in a range of 5 A to 50 A. Moreover, the vertical interconnects 114 can be suitably selected to provide efficient thermal pathways from circuit components to an external device, such as a PCB, heat sink, etc. The vertical interconnects 114 can provide a through current pathway to a system motherboard (or to other component(s)). In various implementations, the vertical interconnects 114 can comprise a material that is conductive and attachable to the substrate 106, substrate 116, and/or other components. For example, the vertical interconnects 114 can comprise a metal, such as copper, gold, or other suitable metal. In some implementations, the interconnects 114 can comprise a non-reflowable material that is highly conductive to heat and electricity (e.g., copper, gold, silver, etc.). In some implementations, the interconnects 114 can include an electroplated plastic, a doped semiconductor (e.g., doped silicon). The vertical interconnects 114 can be attached to the substrate 106 and/or substrate 116, to each other, or to other materials by way of a conductive adhesive (such as solder, a conductive epoxy (e.g., a silver-containing epoxy)). In various implementations, the vertical interconnects 114 can be sintered to the substrate 106, substrate 116, and/or to each other, for example using a metallic mixture (e.g., silver and/or copper mixture). The thermal conductance of the interconnection can have a k-value of greater than or equal to 20.

The vertical interconnect arrays 112 and/or vertical interconnects 114 can be picked and placed onto the respective substrates 106, 116 using pick and place techniques and adhered using the bonding materials and methods described above. The ends 114a, 114b of the vertical interconnects 114 can protrude through the molding compounds 115 in any suitable manner for facilitating electrical connections. The ends 114a, 114b can form a pad. Once the vertical interconnect arrays 112 are attached to the substrates 106, 116, the electronic assembly 100 can be reflowed. Reflow is a soldering technique utilized in surface-mount technology (SMT). The reflow process can involve the controlled application of heat to a conductive adhesive between electronic components (electronic components 108, vertical interconnect arrays 112, etc.) and a substrate (e.g., substrate 106 and/or substrate 116). Reflow can create a reliable and strong connection between the components and the substrate, enabling electrical and mechanical connections. It is during reflow that vertical connects having a high aspect ratio are susceptible to tilt and/or rotate.

The vertical interconnect arrays 112 can be laterally inset relative to an outermost side surface 132 of the electronic assembly 100 (e.g., such that no portion of the vertical interconnect arrays 112 and/or vertical interconnects 114 are exposed on the outermost side surface 132 of the electronic assembly 100) of FIG. 1. For example, the outermost side surface 132 of the electronic assembly 100 may be at least partially defined by the exterior surface of the mold compound 110 and/or a side surface of the substrate 106 and/or substrate 116. By embedding the vertical interconnects 114 within the molding compound 115 and in setting the vertical interconnect arrays 112 relative to the side surface 132 of the electronic assembly 100, the risk of shorting to external electrical components (such as components mounted to the system motherboard) can be reduced.

Moreover, the molding compound 115 of one or more vertical interconnect arrays 112 can face one another and/or be disposed adjacent one another. In some arrangements, there may be a seam between the respective molding compounds 115 of the vertical interconnect arrays 112 as two or more molded structures are positioned adjacent to one another (i.e., the molding compounds 115 of the vertical interconnect arrays 112 are not a unitary body and distinguishable joints are present). In other implementations, a gap can form between the molding compounds 115 of the two or more vertical interconnect arrays 112. In some examples, the seam can be due to, for example, an intervening adhesive (e.g., a conductive adhesive such as solder) that connects the vertical interconnect arrays 112 and which may space the respective molding compound 115 from one another. The electronic components 108 and vertical interconnect arrays 112 can be disposed between the substrate 106 and substrate 116 of the integrated device packages 102, 104.

The vertical interconnects 114 can be generally straight in some implementations. For example, the vertical interconnects 114 can have a first end 114a attached to the substrate 106 and a second opposite end 114b attached to the substrate 116. In some implementations, at least one line perpendicular to the substrate 106 and substrate 116 can extend through both the first and second ends. Moreover, the vertical interconnects 114 can be oriented perpendicular to the substrate 106 and substrate 116. In some implementations, a horizontal cross-sectional of the vertical interconnects 114 perpendicular to the length L (parallel to the longest side of the substrate 106) may not substantially vary along the length L. In various implementations, the vertical interconnects 114 can comprise pillars that have a rounded (e.g., circular or elliptical) cross-section or a polygonal (e.g., rectangular) cross-section. The vertical interconnects 114 can be wider or can have a larger cross-sectional area than lead frame substrates. The shape and size of the vertical interconnects 114 disclosed herein can beneficially enable high currents through the vertical interconnects 114.

The vertical interconnects 114 can have an aspect ratio defined by the ratio of a Height H or Length L of the vertical interconnects 114 to a Width W (perpendicular to the longest side of the substrate 106) or diameter of the vertical interconnects 114. The aspect ratio can be greater than 1:1, for example, in a range of 1:1 to 10:1, in a range of 1:1 to 5:1, in a range of 1:1 to 3:1, in a range of 2:1 to 7:1, or in a range of 2:1 to 5:1. In some implementations, the aspect ratio can be less than 1:1, for example, in a range of 0.2:1 to 1:1. In various implementations, the length L of the vertical interconnects 114 can be in a range of 0.15 mm to 8 mm, in a range of 0.15 mm to 7 mm, in a range of 0.15 mm to 5 mm, or in a range of 0.5 mm to 5 mm. In various implementations, a cross-sectional area of the vertical interconnects 114 taken perpendicular to a length L of the vertical interconnects 114 can be at least 0.5 mm². For example, the cross-sectional area can be in a range of 0.5 mm² to 9 mm², in a range of 0.5 mm² to 5 mm², or in a range of 0.8 mm² to 5 mm². The length L of the vertical interconnects 114 can be in a range of 0.8 mm to 5 mm, in a range of 0.8 mm to 4 mm, in a range of 0.8 mm to 3 mm, in a range of 0.8 mm to 2 mm, in a range of 1 mm to 3 mm, or in a range of 1 mm to 2 mm. In various implementations, a Width W of the vertical interconnects 114 can be in a range of 0.5 mm to 2 mm or in a range of 0.5 mm to 1.5 mm. The use of such relatively large vertical interconnects 114 can beneficially enable the use of high currents through the vertical interconnects 114.

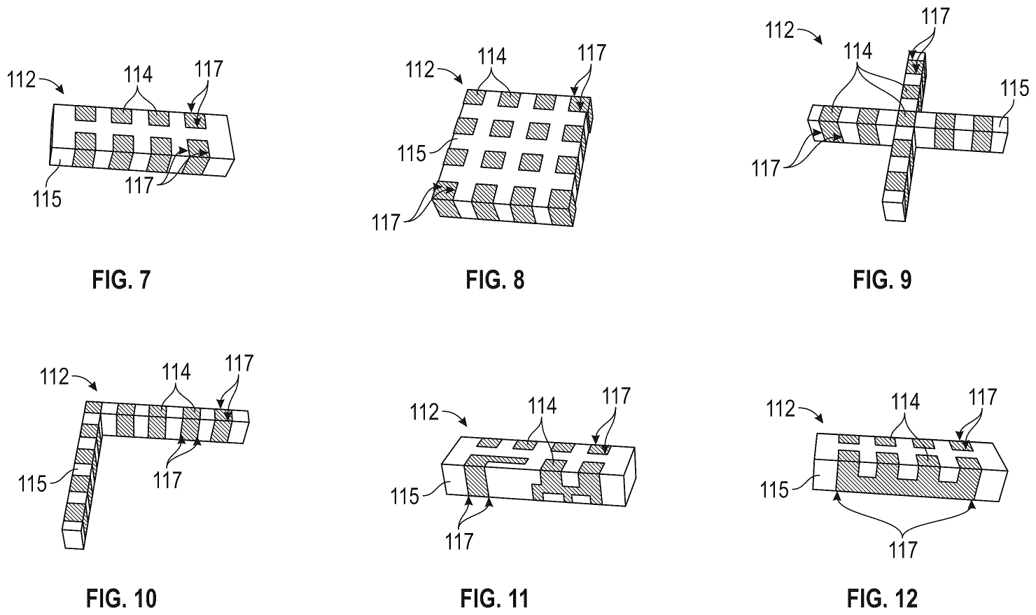

FIG. 7-12 illustrate various perspective views of example vertical interconnect arrays 112 with multiple vertical interconnects 114. The molding compound 115 can encapsulate all or fewer than all lateral sides 117 of the vertical interconnects 114. For example, FIG. 7 illustrates a vertical interconnect array 112 having a two by four configuration of vertical interconnects 114. In another implementation, shown in FIG. 6, a vertical interconnect array 112 can have a four by four arrangement of the vertical interconnects 114. As seen in another implementation as depicted in FIG. 7, a vertical interconnect array 112 can have a cross arrangement of vertical interconnects 114 in which a configuration of five vertical interconnects 114 is perpendicular to another configuration of five vertical interconnects 114 while sharing a common central vertical interconnect 114. FIG. 8 illustrates another implementation of the vertical interconnect array 112 that includes two five by one arrays of vertical interconnects 114 sharing a common end vertical interconnect 114. Lastly, FIGS. 9 and 10 illustrate vertical interconnect arrays 112 with vertical interconnects 114 having non-symmetrical shapes. For example, the vertical interconnects 114 of FIGS. 9 and 10 can be shaped for particular contact arrangements of the first integrated device package 102 and the second integrated device package 104.

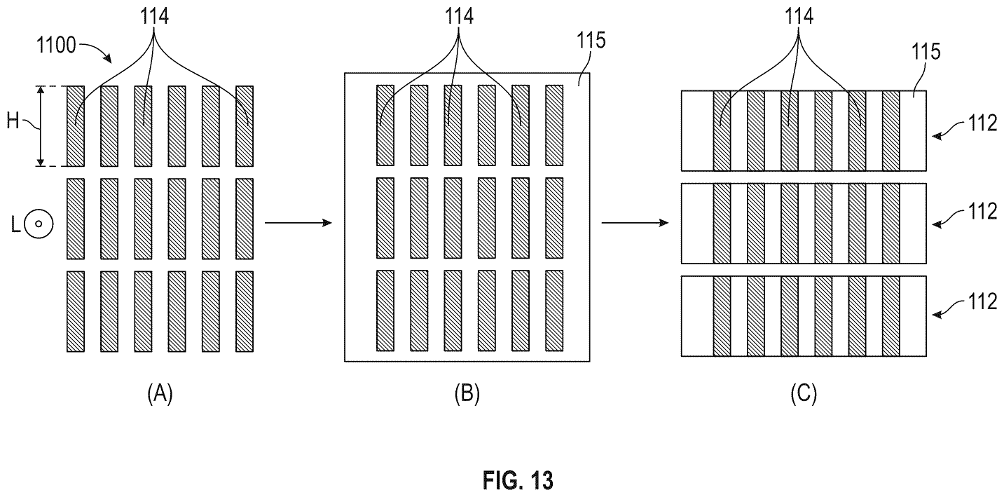

FIG. 13 illustrates an example process 1100 of processing vertical interconnect arrays 112 having a horizontal orientation such that a Height H (long axis) of the vertical interconnects 114 is greater than a Length L (axis extending out of the page), according to an implementation. At (A), a plurality of vertical interconnects 114 can be arranged flat (long axis flat) in an array format. In some implementations, the vertical interconnects 114 can be arranged onto a sacrificial material (e.g., blue tape). At (B), the vertical interconnects 114 of (A) can be transferred or encapsulated by a molding compound 115. At (C), contact points of the vertical interconnects 114 (e.g., first end 114a and/or second end 114b) can be cleaned creating a solid array of high current density connections. The solid array can then be singulated into various vertical interconnect arrays 112 at least based on the application of the vertical interconnect arrays 112. For example, the solid molded array can be singulated into a one-dimensional (e.g., one by x) vertical interconnect arrays 112. In other implementation, the solid molded array can be singulated into a two-dimensional vertical interconnect arrays 112. The singulated vertical interconnect arrays 112 can then be placed into a tape and reel packaging to provide for a convenient and efficient way to transport, store, and feed the vertical interconnect arrays 112 for surface mounting using SMT equipment.

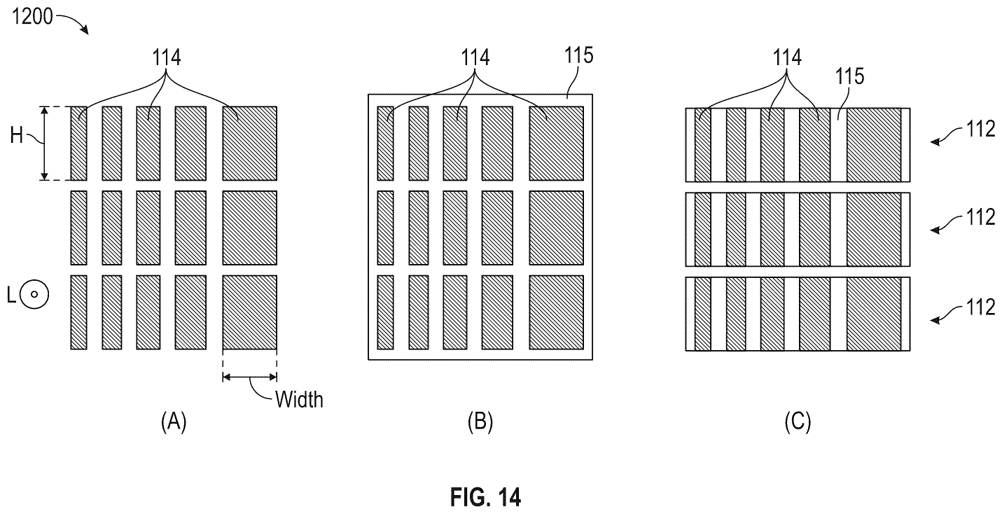

FIG. 14 illustrates an example process 1200 of processing vertical interconnect arrays 112 having a horizontal orientation such that a Height H of the vertical interconnects 114 is greater than a length L (extending into the page), according to an implementation. The process 1200 can be similar and/or identical to the process 1100 except that the vertical interconnects 114 of process 1200 can vary in Width W while maintaining Length L and Height H constant.

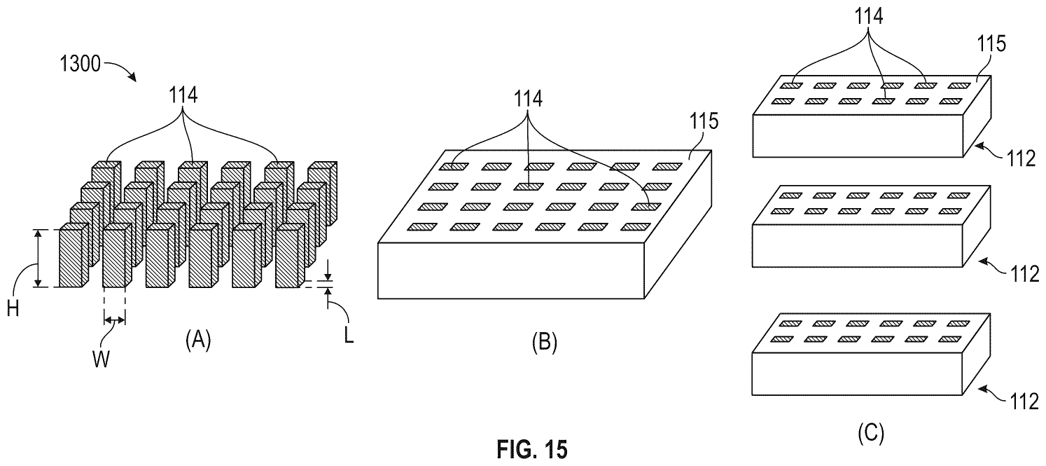

FIG. 15 illustrates an example process 1300 of processing vertical interconnect arrays 112 having a vertical orientation such that a Height H of the vertical interconnects 114 is greater than a Length L, according to an implementation. At (A), a plurality of vertical interconnects 114 can be arranged vertically (long axis perpendicular) in an array format. In some implementations, the vertical interconnects 114 can be arranged onto a sacrificial material (e.g., blue tape). At (B), the vertical interconnects 114 of (A) can be transferred or encapsulated by a molding compound 115. At (C), contact points of the vertical interconnects 114 (e.g., first end 114a and/or second end 114b) can be cleaned creating a solid array of high current density connections. The solid array can then be singulated into various vertical interconnect arrays 112 at least based on the application of the vertical interconnect arrays 112. For example, the solid molded array can be singulated into a one-dimensional (e.g., one by x) vertical interconnect arrays 112. In other implementations, the solid molded array can be singulated into a two-dimensional vertical interconnect arrays 112 as shown in (C). The singulated vertical interconnect arrays 112 can then be placed into a tape and reel packaging to provide for a convenient and efficient way to transport, store, and feed the vertical interconnect arrays 112 for surface mounting using SMT equipment.

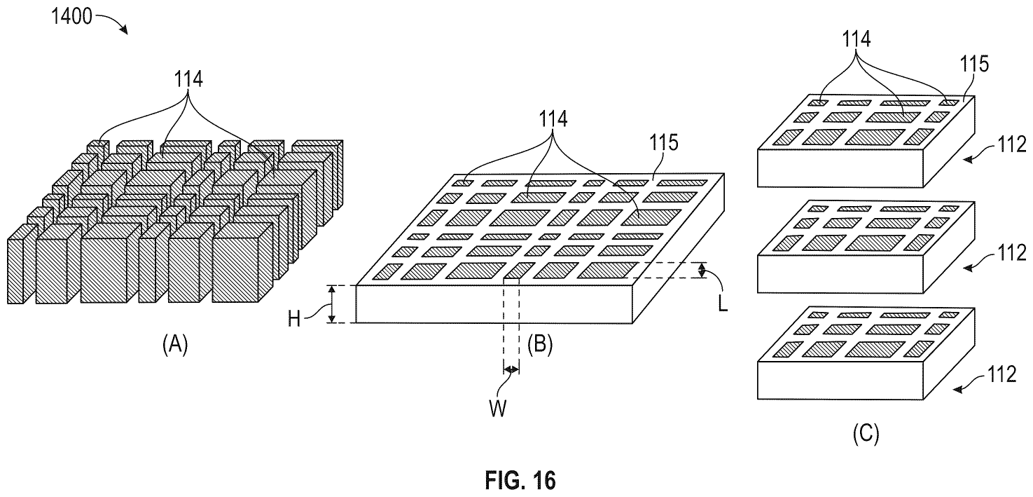

FIG. 16 illustrates an example process 1400 of processing vertical interconnect arrays 112 having a horizontal orientation such that a length of the vertical interconnects 114 is greater than a height, according to an implementation. The process 1200 can be similar and/or identical to the process 1100 except that the vertical interconnects 114 of process 1200 can vary in Width W while maintaining Length L and Height H (not shown) constant.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

Several illustrative examples of molded vertical interconnect arrays and related systems and methods have been disclosed. Although this disclosure has been described in terms of certain illustrative examples and uses, other examples and other uses, including examples and uses which do not provide all of the features and advantages set forth herein, are also within the scope of this disclosure. Components, elements, features, acts, or steps may be arranged or performed differently than described and components, elements, features, acts, or steps may be combined, merged, added, or left out in various examples. All possible combinations and subcombinations of elements and components described herein are intended to be included in this disclosure. No single feature or group of features is necessary or indispensable.

Certain features that are described in this disclosure in the context of separate implementations may also be implemented in combination in a single implementation. Conversely, various features that are described in the context of a single implementation also may be implemented in multiple implementations separately or in any suitable subcombination. Moreover, although features may be described above as acting in certain combinations, one or more features from a claimed combination may in some cases be excised from the combination, and the combination may be claimed as a subcombination or variation of a subcombination.

Further, while illustrative examples have been described, any examples having equivalent elements, modifications, omissions, and/or combinations are also within the scope of this disclosure. Moreover, although certain aspects, advantages, and novel features are described herein, not necessarily all such advantages may be achieved in accordance with any particular example. For example, some examples within the scope of this disclosure achieve one advantage, or a group of advantages, as taught herein without necessarily achieving other advantages taught or suggested herein. Further, some examples may achieve different advantages than those taught or suggested herein.

Some examples have been described in connection with the accompanying drawings. The figures may or may not be drawn and/or shown to scale, but such scale should not be limiting, since dimensions and proportions other than what are shown are contemplated and are within the scope of the disclosed invention. Distances, angles, etc. are merely illustrative and do not necessarily bear an exact relationship to actual dimensions and layout of the devices illustrated. Components may be added, removed, and/or rearranged. Further, the disclosure herein of any particular feature, aspect, method, property, characteristic, quality, attribute, element, or the like in connection with various examples may be used in all other examples set forth herein. Additionally, any methods described herein may be practiced using any device suitable for performing the recited steps.

For purposes of summarizing the disclosure, certain aspects, advantages and features of the inventions have been described herein. Not all, or any such advantages are necessarily achieved in accordance with any particular example of the inventions disclosed herein. No aspects of this disclosure are essential or indispensable. In many examples, the devices, systems, and methods may be configured differently than illustrated in the figures. or description herein. For example, various functionalities provided by the illustrated modules may be combined, rearranged, added, or deleted. In some implementations, additional or different processors or modules may perform some or all of the functionalities described with reference to the examples described and illustrated in the figures. Many implementation variations are possible. Any of the features, structures, steps, or processes disclosed in this specification may be included in any example.

1.-49. (canceled)

50. An integrated device package comprising:
a substrate; and
one or more vertical interconnect arrays comprising a plurality of vertical interconnects in an array and a molding compound encapsulating the plurality of vertical interconnects, wherein the molding compound at a first end and a second end of the one or more vertical interconnect arrays comprise a planar surface, and wherein a first end of the plurality of vertical interconnects is substantially co-planar with the molding compound at the first end of the plurality of vertical interconnects and a second end of the plurality of vertical interconnects is substantially co-planar with the molding compound at the second end of the plurality of vertical interconnects;
wherein the first end of the one or more vertical interconnect arrays is physically and electrically connected to a first side of the substrate, the one or more vertical interconnect arrays extending outwardly from the substrate.

51. The integrated device package of claim 50, wherein the plurality of vertical interconnects are arranged in a horizontal orientation such that a length of the plurality of vertical interconnects is greater than a height.

52. The integrated device package of claim 50, wherein the plurality of vertical interconnects are arranged in a vertical orientation such that a height of the plurality of vertical interconnects is greater than a length.

53. The integrated device package of claim 50, wherein the one or more one or more vertical interconnect arrays comprises a singulated vertical interconnect array.

54. The integrated device package of claim 50, wherein the plurality of vertical interconnects are partially molded such that a at least a portion of a height and one or more sides of the plurality of vertical interconnects protrude through the molding compound.

55. The integrated device package of claim 50, further comprising a second substrate, wherein the second side of the one or more vertical interconnect arrays is physically and electrically connected to a first side of the second substrate by a conductive adhesive, wherein the one or more vertical interconnect arrays are surface mounted to the substrate, wherein the one or more vertical interconnect arrays are connected to the substrate and the second substrate with a conductive adhesive.

56. The integrated device package of claim 55, wherein the conductive adhesive comprises solder or conductive epoxy.

57. The integrated device package of claim 50, further comprising a seam between each of the one or more vertical interconnect arrays connected to the first substrate.

58. The integrated device package of claim 50, wherein the one or more vertical interconnect arrays comprise a one-dimensional array or a two-dimensional array.

59. An integrated device package comprising:
one or more vertical interconnect arrays comprising a plurality of vertical interconnects in an array and a molding compound encapsulating the plurality of vertical interconnects, wherein the molding compound at a first end and a second end of the one or more vertical interconnect arrays comprise a planar surface, and wherein a first end of the plurality of vertical interconnects is substantially co-planar with the molding compound at the first end of the plurality of vertical interconnects and a second end of the plurality of vertical interconnects is substantially co-planar with the molding compound at the second end of the plurality of vertical interconnects arrays;
a first substrate, wherein the first end of the one or more vertical interconnect arrays is physically and electrically connected to a first side of the substrate;
a second substrate, wherein the second end of the one or more vertical interconnect arrays is physically and electrically connected to a first side of the second substrate; and
a seam between each of the one or more vertical interconnect arrays connected to the first and second substrate;
wherein the one or more vertical interconnect arrays are disposed between the first and second substrates.

60. The integrated device package of claim 59, wherein the plurality of vertical interconnects are arranged in a horizontal orientation such that a length of the plurality of vertical interconnects is greater than a height or in a vertical orientation prior to encapsulating such that a height of the plurality of vertical interconnects is greater than a length.

61. The integrated device package of claim 59, wherein the molding compound encapsulating the plurality of vertical interconnects is singulated prior to mounting the one or more vertical interconnect arrays.

62. The integrated device package of claim 59, wherein the plurality of vertical interconnects are partially molded such that a section of a height and one or more sides of the plurality of vertical interconnects protrude through the molding compound.

63. The integrated device package of claim 59, wherein the one or more vertical interconnect arrays are surface mounted to the first substrate and the second substrate with a conductive adhesive, wherein the conductive adhesive comprises solder or conductive epoxy.

64. The integrated device package of claim 59, wherein the molding compound is flush with the first end and the second end of the plurality of vertical interconnects.

65. A method of forming an electronic module, the method comprising:
arranging a plurality of vertical interconnects in an array;
encapsulating the plurality of vertical interconnects in a molding compound, wherein a first end and a second end of the plurality of vertical interconnects protrude through the molding compound; and
after the encapsulating, singulating the encapsulated plurality of vertical interconnects in an array into a plurality of vertical interconnect arrays.

66. The method of claim 65, further comprising planarizing a first surface of the plurality of vertical interconnect arrays and a second surface opposite the first surface.

67. The method of claim 65, further comprising mounting a first end of at least one of the plurality of molded vertical interconnects to a substrate.

68. The method of claim 65, further comprising mounting a second end of the at least one of the plurality of molded vertical interconnects to a second substrate.

69. The method of claim 67, further comprising disposing the plurality vertical interconnect arrays onto a tape and reel for mounting.
